(19) United States
(12) Patent Application Publication
(10) Pub. No.: US 2008/0212261 A1
(43) Pub. Date: Sep. 4, 2008

(54) Energy storage devices and composite articles associated with the same

(75) Inventors: Pulickel M. Ajayan, Clifton Park, NY (US); Robert J. Linhardt, Albany, NY (US); Omkaram Nalamasu, Niskayuna, NY (US); Ashavani Kumar, Troy, NY (US); Saravanababu Murugesan, Plainsboro, NJ (US); Shaijumon M. Manikoth, Troy, NY (US); Victor L. Pushparaj, Troy, NY (US)

Correspondence Address: WOLF GREENFIELD & SACKS, P.C., 600 ATLANTIC AVENUE, BOSTON, MA, 02210-2206, US

(73) Assignee: Rensselaer Polytechnic Institute, Troy, NY (US)

(21) Appl. No.: 11/509,316

(22) Filed: Aug. 24, 2006

Related U.S. Application Data
(60) Provisional application No. 60/818,921, filed on Jul. 5, 2006.

(51) Int. Cl. H01G 9/00; H01M 10/40; H01B 1/24; H01M 10/36; H01G 9/022; C23C 16/44; B29C 39/02; H01G 9/035

(52) U.S. Cl. 361/502; 429/122; 252/500; 252/511; 429/188; 252/62.2; 427/255.28; 264/299; 361/503; 361/505; 977/742

(57) ABSTRACT

Embodiments of the invention relate to energy storage devices, e.g., capacitors and batteries, that may include a composite article of elongated conductive structures embedded in a polymer matrix. In some embodiments, a liquid containing ionic species may be dispersed within the polymer matrix of the article. The liquid may contact the elongated conductive structures within the polymer matrix. When the composite article is used as an energy storage device, the large surface area at the interface between the elongated conductive structures and the liquid can provide high energy storage. Embodiments of the invention enable storing energy using a composite article that exhibits both high and low temperature stability, high cyclic repeatability, and mechanical flexibility. The composite article can also be non-toxic, biocompatible and environmentally friendly. Thus, the composite article may be useful for a variety of energy storage applications, such as in the automotive, RFID, MEMS and medical fields.

### RELATED APPLICATIONS

This application claims priority under 35 U.S.C. § 119(e) to U.S. Provisional Application Ser. No. 60/818,921, entitled “COMPOSITE ARTICLES AND ENERGY STORAGE DEVICES ASSOCIATED WITH THE SAME,” filed on Jul. 5, 2006, which is hereby incorporated by reference in its entirety.

### FIELD OF INVENTION

The invention relates generally to energy storage devices and methods associated with such structures, as well as composite articles and, more particularly, to composite articles formed of a polymeric matrix and elongated conductive structures.

### BACKGROUND OF INVENTION

Energy storage devices include electrochemical capacitors (e.g., supercapacitors) and batteries.

Electrochemical capacitors, including supercapacitors, are promising power sources for portable systems and automotive applications. Conventional capacitors typically have capacitances on the order of micro Farads or pico Farads. Supercapacitors having much higher capacitance have been developed since the 1990's. Supercapacitors also have high power densities, which can be advantageous in electrical energy storage device applications.

The performance characteristics of electrochemical capacitors are determined, in part, by the structural and electrochemical properties of electrodes. Various materials including doped conducting polymer, metal oxides, metal nitrides, and carbon in various forms have been studied for use as electrode materials. Carbon-based supercapacitor electrodes have been attractive due to their high surface area and porous nature. Recently, carbon nanotubes have been used as electrodes for electrochemical double layer capacitors (e.g., See, Frackowiak and Beguin, Electrochemical storage of energy in carbon nanotubes and nanostructured carbons; Carbon 40 (2002) 1775). Supercapacitors using a combination of single walled carbon nanotubes and polymer composites as electrode materials have been described in U.S. Pat. No. 7,061,749 (Liu) in which an electrolyte-permeable separator or spacer was interposed between the electrodes. In such capacitors, use of a liquid electrolyte and a separator can lead to limitations.

Conventional supercapacitor electrode fabrication procedures typically involve various steps such as physical mixing of the active electrode material with binders and annealing treatments which are important for decreasing the charge-transfer resistance. A porous, electrically insulating separator may be sandwiched between the two electrodes. Such processes may be complex and have other disadvantages.

Batteries are typically used as energy storage devices for systems such as portable electronic devices and electric or hybrid gas-electric automobiles. Significant work has been devoted to the electrode materials for batteries and, in particular, for cathode materials of lithium batteries. Lithium batteries have an anode containing an active material for releasing lithium ions during discharge.

Carbon nanotubes also have been considered as electrode materials, including as cathode materials for lithium batteries. For example, Japanese Patent No. 2,513,418, which corresponds to JP-A-5-175929, discloses a cathode containing carbon nanotubes. Carbon nanotubes obtained by electric discharge have been used as cathode electrodes. Lithium batteries using lithium doped transition metal alloy oxides as cathode material and carbon nanotubes as anode material have also been described, as in U.S. Pat. No. 7,060,390 (Chen).

Conventional techniques using carbon nanotubes as electrode materials in batteries may involve several steps including mixing the nanotubes with conductive binders and performing annealing treatments, which increases the equivalent resistance and effectively reduces the performance of the battery.

In general, there exists a need to provide energy storage devices (e.g., electrochemical capacitors and batteries) that overcome limitations of conventional devices and methods of forming the same, including those described above. In particular, it would be desirable for the energy storage devices to exhibit stability, flexibility, biocompatibility, ease of packaging and be fabricated from relatively environmentally benign materials. It would also be desirable for the electrodes of such energy storage devices to have a high accessible surface area, high porosity and high conductivity. There also exists a need for a method of producing such electrodes which is simple, inexpensive, and readily repeatable.

### SUMMARY OF INVENTION

Composite articles formed of a polymeric matrix and elongated conductive structures are provided, as well as energy storage devices and methods associated with such articles.

Various aspects of the invention will be addressed. A given embodiment may practice one aspect or multiple aspects of the invention. Thus, there is no intention that aspects be understood to be mutually exclusive, even though certain pairs of aspects may, in fact, be mutually exclusive.

In one aspect, the invention relates to an energy storage device that includes a non-conductive polymer matrix and a first electrode comprising first elongated conductive structures embedded in the polymer matrix. The energy storage device also includes a second electrode and a liquid that includes ionic species. The liquid is contained within the polymer matrix. In some embodiments, the energy storage device may be a capacitor or a battery.

In another aspect, the invention relates to a composite article that includes a non-conductive polymer matrix and a plurality of elongated conductive structures embedded in the polymer matrix. The composite article also includes a liquid comprising ionic species contained within the polymer matrix. The composite article may be used, for example, in an energy storage device.

In yet another aspect, the invention relates to a method of forming a composite article that may be used in an energy storage device. The method includes forming a set of elongated conductive structures and infiltrating the set of elongated conductive structures with a solution of polymer and liquid. The composite article is formed such that the elongated conductive structures are embedded in a non-conductive polymer matrix.

Other aspects, embodiments and features of the invention will become apparent from the following detailed description of the invention when considered in conjunction with the accompanying drawings. The accompanying figures are schematic and are not intended to be drawn to scale. In the figures, each identical, or substantially similar component that is illustrated in various figures is represented by a single numeral or notation.

For purposes of clarity, not every component is labeled in every figure. Nor is every component of each embodiment of the invention shown where illustration is not necessary to allow those of ordinary skill in the art to understand the invention. All patent applications and patents incorporated herein by reference are incorporated by reference in their entirety. In case of conflict, the present specification, including definitions (if any), will control.

### BRIEF DESCRIPTION OF DRAWINGS

FIG. 1 shows a composite article according to an embodiment of the invention;

FIG. 2 shows a capacitor according to an embodiment of the invention;

FIG. 3 shows a battery according to an embodiment of the invention;

FIG. 4 shows a method of forming a composite article, according to an embodiment of the invention;

FIG. 5 shows a photograph illustrating the flexibility of a composite article according to an embodiment of the invention;

FIG. 6 shows images of elongated conductive structures and a polymer matrix, according to an embodiment of the invention;

FIGS. 7A-7B show plots illustrating experimental results of the electrical parameters of a capacitor, according to an embodiment of the invention;

FIG. 8 shows a plot illustrating experimental results of the electrical performance of a battery, according to an embodiment of the invention;

FIG. 9 shows images of aligned elongated conductive structures, according to an embodiment of the invention;

FIGS. 10A-10B, respectively, show cyclic voltammograms and charge-discharge curves of supercapacitors having particular electrolytes, according to one embodiment of the invention;

FIGS. 11A-11B, respectively, show plots of capacity vs. voltage and capacity vs. cycle for a battery, according to one embodiment of the invention;

FIGS. 12A-12B, respectively, show plots of power density vs. temperature and cyclic voltammograms at various temperatures, according to one embodiment of the invention; and

FIGS. 13A-13B, respectively, show a cyclic voltammogram and a charge-discharge curve of a supercapacitor that uses perspiration, e.g., sweat, as the supercapacitor electrolyte, according to one embodiment of the invention.

### DETAILED DESCRIPTION

Embodiments of the invention relate to a composite article that may include elongated conductive structures at least partially embedded in a polymer matrix. As described further below, the composite article may be used to form energy storage devices including, for example, capacitors, batteries and fuel cells, and may also be used in solar cells. In some embodiments, a liquid containing ionic species may be contained within the polymer matrix of the article, and the liquid may contact the elongated conductive structures within the polymer matrix. When the composite article is used in an energy storage device, the large surface area at the interface between the elongated conductive structures and the liquid can provide high energy storage. Embodiments of the invention enable storing energy using a composite article that exhibits both high and low temperature stability, high cyclic repeatability, and mechanical flexibility. The composite article can also be non-toxic, biocompatible and environmentally friendly. Thus, the composite article may be useful for a variety of energy storage applications, such as in electric and hybrid vehicles in the automotive field, and also in applications in the RFID and medical fields.

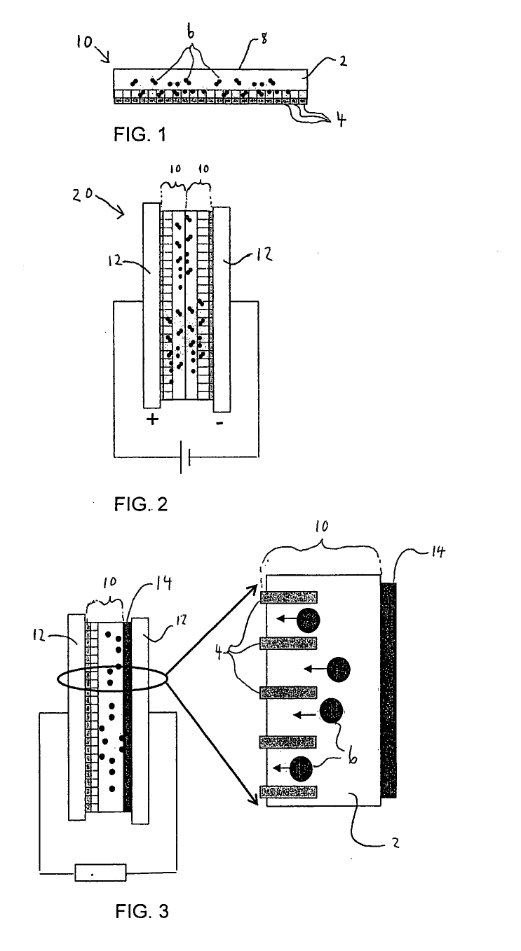

FIG. 1 illustrates one embodiment of a composite article 10. The article includes a non-conductive polymer matrix 2, and a plurality of elongated conductive structures 4 embedded in the polymer matrix. A liquid 6 having ionic species is contained within the polymer matrix. Thus, composite article 10 is a relatively simple structure that may be used to form different energy storage devices, such as capacitors and batteries. When used in energy storage applications, the simplicity of composite article 10 is advantageous at least partly because of the reduction in packaging complexity required relative to prior art energy storage devices. Various aspects of composite article 10 will now be described in further detail.

Any suitable polymer and/or block co-polymer may be used as the polymer matrix 2. In some embodiments of the invention, it is preferable that the polymer matrix is non-conductive. As used herein, the term “non-conductive” means that the material is an electrical insulator, e.g., having a resistivity of greater than approximately 10¹⁰ Ohm·meter, and preferably greater than approximately 10¹⁶ Ohm·meter. A polymer matrix with a low conductivity value and/or high resistance value may prevent the shorting out of an energy storage device that may be formed using the composite article. In some embodiments, polymer matrix 2 may be a hydrophilic polymer. In some embodiments, polymer matrix 2 may be a hydrophobic polymer. In some embodiments, polymer matrix 2 may be cellulose and/or a modified cellulose material. If polymer matrix 2 is a type of cellulose material, cellulose units are attracted to one another via hydrogen bonding. As another example, polymer matrix 2 may be polyethylene oxide (PEO). Polymer matrix 2 may be formed of an organic polymer or an inorganic polymer, as the invention is not limited in this respect.

The elongated conductive structures may be embedded in the polymer matrix. The term “embedded” means that a portion of an elongated conductive structure is surrounded, at least in part, by the polymer matrix. An embedded elongated conductive structure may lie within the polymer matrix without being chemically bonded to the polymer. However, the elongated conductive structure may be physically bonded to the matrix and/or chemically bonded to the polymer matrix, as the invention is not limited in this respect. If the elongated conductive structures are carbon nanotubes and the polymer matrix is cellulose, the carbon nanotubes may be attracted to the polymer of the polymer matrix. The term “polymer matrix” is not simply a coating of polymer formed on the elongated conductive structures. Rather, the polymer matrix may have a significant three-dimensional structure. The polymer matrix provides a framework for the body of the composite article and the elongated conductive structures that lie therein. If the polymer matrix is a film, the thickness of the film may be of approximately the same order of magnitude as the length of the elongated conductive structures, for example. The polymer matrix may have a porous structure, enabling liquid 6 to pass through the pores and thereby be dispersed (e.g., contained) within the polymer matrix and to contact the elongated conductive structures therein. The polymer matrix can be shaped or molded to impart the resulting article with a desirable three-dimensional shape, as described further below.

In some embodiments, a portion of the embedded filaments may be exposed so that electrical contact can be made thereto by a metal contact or any other suitable electrically conductive contact material.

The polymer matrix may be formed in any suitable shape or size. In one example, polymer matrix 2 may be a film. For example, the film may have a thickness between 0.1 and 3 millimeters. In some embodiments, the film may have a thickness between 0.3 millimeters and 1 millimeter. Polymer matrix 2 may be porous, such that the elongated conductive structures 4 are embedded in the pores of the polymer matrix. Liquid 6 may permeate through the pores in one or more regions of the polymer matrix 2. In some embodiments, the liquid 6 may permeate substantially throughout the polymer material.

Elongated conductive structures 4 may be formed of any suitable type of conducting material. In certain preferred embodiments, the elongated conductive structures 4 may be formed of carbon, such as carbon nanotubes. If carbon nanotubes are used, they may be modified or unmodified, functionalized or non-functionalized, and multi-walled or single-walled or any suitable combination thereof. In some embodiments, the elongated conductive structures 4 may be formed of one or more metal oxides and/or conducting polymers. However, the elongated conductive structures may be formed of any suitable material, as the invention is not limited in this respect. In some embodiments, the elongated conductive structures may be formed of more than one material. Any suitable type or shape of elongated conductive structures may be used, such as filaments, nanotubes or nanowires.

The elongated conductive structures 4 may have any suitable length, for example between 10 microns and 5 millimeters. In some embodiments, the length may be between approximately 50 and 500 microns. The elongated conductive structures may have an aspect ratio (i.e., length/width) of greater than 1, and, more typically, greater than 5:1 or 10:1. The elongated conductive structures are conductive, e.g., such that they have an electrical conductivity of greater than approximately 10³ S/cm. The elongated conductive structures 4 may have any suitable orientation. In some embodiments, at least some, most (e.g., 50% or more), or substantially all of the filaments may be aligned with one another. For example, at least some, or substantially all, of the filaments may be aligned in an orientation that is perpendicular to a substrate or conductive material on which the elongated conductive structures 4 are disposed. If the composite article is formed in the shape of a film, a substantial portion of the elongated conductive structures 4 may be aligned with one another in an orientation that is perpendicular to a main surface 8 of the film.

Elongated conductive structures 4 may be arranged in patterned bundles or a continuous array of filaments. Elongated conductive structures 4 may contact each other or not, as the invention is not limited in this respect. The elongated conductive structures may be embedded in the polymeric matrix such that only a portion (e.g., respective end portions) of at least some of the elongated conductive structures are exposed and remaining portions of the at least some of the elongated conductive structures are surrounded by the polymeric matrix. At least some of the elongated conductive structures may have exposed portions to provide electrical contact to the elongated conductive structures. In some embodiments, liquid 6 contacts the elongated conductive structures within the polymer matrix.

Liquid 6 is contained within the polymer matrix. In some embodiments, it is preferable for liquid 6 to be dispersed throughout the polymer matrix. Such a structure may allow liquid 6 to contact elongated conductive structures 4 over a large surface area, which can provide an increased energy storage capability. Liquid 6 may be any suitable liquid having any suitable ionic species. Liquid 6 may be an aqueous solution of a compound or a non-aqueous solution. For example, the liquid 6 may be an electrolyte. In some embodiments, liquid 6 may be an ionic liquid, e.g., a room temperature ionic liquid such as 1-butyl-3-methylimidazolium chloride ([bmIm][Cl]). As another example, the liquid may be sulfuric acid, potassium hydroxide, sodium hydroxide, propylene carbonate, dimethoxy ethanol, diethyl carbonate or acetonitrile. As further examples, the liquid may include LiClO₄, NaClO₄, LiAsF₆, BF₄ or quarternary phosphonium salts. However, any suitable liquid may be used, as the invention is not limited in this respect. In some embodiments, liquid 6 may be a bodily fluid (e.g., perspiration, urine, blood, saliva and/or synovial fluid), which may enable a variety of unique energy storage device applications, as described further below.

In some embodiments, liquid 6 may be capable of dissolving the polymer that makes up polymer matrix 2. Dissolving the polymer in liquid 6 may facilitate forming composite article 10 having elongated conductive structures embedded in a polymer matrix 2. The formation of polymer matrix 2 will be discussed in further detail below. The amount of liquid present in the polymer matrix may be between about 0.01% and 50% of the total weight of the composite article. In some embodiments, the amount of liquid may be between about 5% and 30% of the total weight of the composite article.

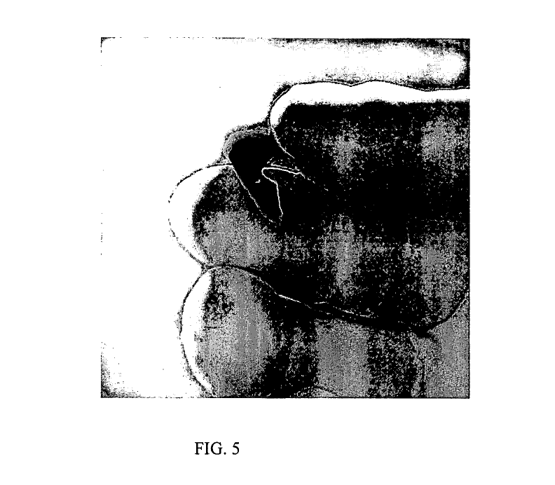

As illustrated in FIG. 5, composite article 10 can exhibit a high degree of mechanical flexibility, enabling bending of the structure with little or no change in performance. This flexibility may make composite article particularly useful for medical applications, in which structure 10, capacitor 20 and/or battery 30 may be used to provide a flexible power source for a device, e.g., an implant. As another example, they may be used in clothing to provide portable energy storage, as may be desirable in a variety of scenarios, such as in wearable computing applications. Composite article 10 may be designed to be attached to a human or animal body. Composite article 10 may be non-toxic and biocompatible, enabling the composite article 10 to be designed to be implantable in a human or animal body.

Any one or more of a variety of liquids may be used in the composite article, including a bodily fluid such as perspiration, urine, blood, saliva and/or synovial fluid. Using a bodily fluid as liquid 6 enables the fabrication of self-sustainable capacitor devices, which may overcome possible packaging problems arising from use of pre-packaged liquid electrolytes which, in turn, may leak and/or cause corrosion over time, and which may be toxic. A bodily fluid may be used in a composite article as liquid 6 in various medical applications, such as in patient monitoring and/or diagnosis. A bodily fluid may be particularly useful as liquid 6 when used in an implantable device. For example, a biocompatible composite article having bodily fluid (e.g., blood), as liquid 6 may be used as part of an implantable sensor for in vivo patient measurements and/or monitoring. As another example, a composite article having bodily fluid (e.g., perspiration) as liquid 6 may be used as a non-implantable sensor for patient measurements and/or monitoring. Any suitable characteristic of the bodily fluid may be measured using such a sensor. As one example, a patient's electrolyte level may be measured based on the conductivity of the bodily fluid. In some embodiments, a composite article having bodily fluid as liquid 6 may be used in an energy storage device designed for an implantable medical device (e.g., a pacemaker). A composite article using bodily fluid may also be useful in non-medical applications. For example, a composite article having bodily fluid as liquid 6 may be used a part of a sensor that measures the amount of fluid lost by an athlete, a sensor that detects the mood and/or degree of nervousness in a human subject (e.g., a lie-detector test), an energy storage device for a heart-rate monitor, a watch, and in any other suitable application.

Composite article 10 may be environmentally friendly such that it is easily disposed of without harm to the environment. Composite article 10 may be capable of operating at extreme high and low temperatures, and may be designed to be stable to autoclaving, exposure to radiation and/or ethylene oxide washing. The advantages of composite article 10 can also apply to capacitor 20 and battery 30, which will be described in further detail below. Further applications of the composite article include other energy storage and energy generation devices such as fuel cells and solar cells. If, for example, the composite article is used in a solar cell, the elongated conductive filaments may generate current when exposed to electromagnetic radiation, e.g., sunlight.

The composite article 10 illustrated in FIG. 1 can be used to form energy storage devices such as capacitors and batteries, as will be discussed in further detail below with respect to FIGS. 2 and 3. However, the invention is not limited to the structure illustrated in FIG. 1, as any suitable structure may be used. Energy storage devices according to the invention may be used in a variety of applications, such as automotive, RFID and medical applications. For example, the energy storage devices may provide energy to a temperature sensor, switch, drug delivery device, pacemaker, implantable device (e.g., a pump) and/or artificial organ. Embodiments of the invention may be useful in portable (e.g., mobile) devices, such as cell phones, portable music players, personal digital assistants (PDAs) and laptop computers. Additionally, embodiments of the invention may be useful in providing power to sensors and actuators, and to small-scale devices such as microelectromechanical systems (MEMS), nanoelectromechanical systems (NEMS) or a system on a chip, or to other battery-powered devices.

The energy storage device can be designed to operate in an aqueous environment, or non-aqueous environment. If the energy storage device is used in a medical application, it may be shaped to be implanted within a portion of the human body. In an automotive application, it may be shaped to fit within a portion of an automobile. Embodiments of the invention may be used to store energy in electric or hybrid vehicles. For example, a supercapacitor made in accordance with the invention may be used to store energy generated by a regenerative braking system in an electric or hybrid vehicle.

FIG. 2 illustrates an example of a capacitor 20, according to one embodiment of the invention. The capacitor may be a supercapacitor, such as a double-layer capacitor. A double-layer capacitor is a type of capacitor that stores energy in the electric field that is established by the charge-separation at the interface between two materials. Since the capacitance may be proportional to the surface area of the interface, increasing the surface area of the interface can increase the amount of energy stored in the device. Some embodiments of the invention enable providing a large amount of energy storage in a capacitor by providing a large surface area at the interface between elongated conductive structures 4 and liquid 6. In one embodiment, capacitor 20 is formed using two of the composite articles 10 illustrated in FIG. 1. As illustrated in FIG. 2, the composite articles 10 may contact each other along main surfaces 8, bringing the polymer 2 from both structures into contact. When the composite articles 10 are in contact in this manner, liquid 6 may flow freely between the structures, e.g., via the pores of the polymer, effectively providing a single region of the liquid 6 within the capacitor 20. The liquid 6 may contact the elongated conductive structures 4 at both sides of capacitor 20. Therefore, the first set of elongated conductive structures 4 corresponding to the first composite article 10 (e.g., on the left side of FIG. 2) may form a first electrode of capacitor 20. The second set of elongated conductive structures 4 corresponding to the second composite article (e.g., on the right side of FIG. 2) may form a second electrode of capacitor 20. The two sets of elongated conductive structures may be in contact with respective electrical conductors 12, thereby providing terminals for connecting device 20 to external electrical components. The electrodes may be in the form of a film, fiber, fabric, felt, mat and/or any combination thereof or other convenient form. Capacitor 20 may advantageously not need a separate non-conducting spacer to prevent the shorting out of the capacitor electrodes because polymer matrix 2 is itself non-conductive.

Advantageously, capacitors formed of at least one composite article 10 may have a very high capacitance value. In particular, the interface between the liquid 6 and the filaments 4 provides a large effective surface area. Experimental results have demonstrated that a capacitance density of at least 36 Farads/gram is achievable, as described further below, and this is not considered as a limit. Furthermore, capacitor 20 has been tested and performs in the temperature range from 195° K to 423° K. Capacitor 20 can withstand temperatures at least as low as 77° K, and still regain capacitive behavior at 195° K.

FIG. 3 illustrates an example of a battery 30, according to another embodiment of the invention. Battery 30 includes a composite article 10, as described above with respect to FIG. 1. The first electrode (e.g., cathode) of battery 30 is formed of elongated conductive structures 4. In this embodiment, the second electrode 14 (e.g., the anode) of battery 30 is formed of a suitable material for providing an electrochemical reaction at the surface of second electrode 14. Electrode 14 may be formed of any suitable material. For example, in the case that battery 30 is a lithium battery, electrode 14 may be formed of metallic lithium. In this case, liquid 6 may include LiPF₆, LiClO₄, LiAsF₆ and/or Li salt(s). However, battery 30 need not be based on lithium chemistry, as any other suitable chemistry may be used, and the appropriate electrode and liquid type may be chosen accordingly.

It should be appreciated that the invention is not limited to the structure of capacitor 20 or battery 30 as illustrated in FIGS. 2 and 3. For example, a capacitor could be formed of one composite article 10 for one electrode, and a second electrode may be formed without a composite article 10, in any suitable way. Furthermore, it is appreciated that capacitor 20 and battery 30 may be formed in any suitable shape, and the shape may be chosen to fit in a particular region of an object, such as an automobile or the human body.

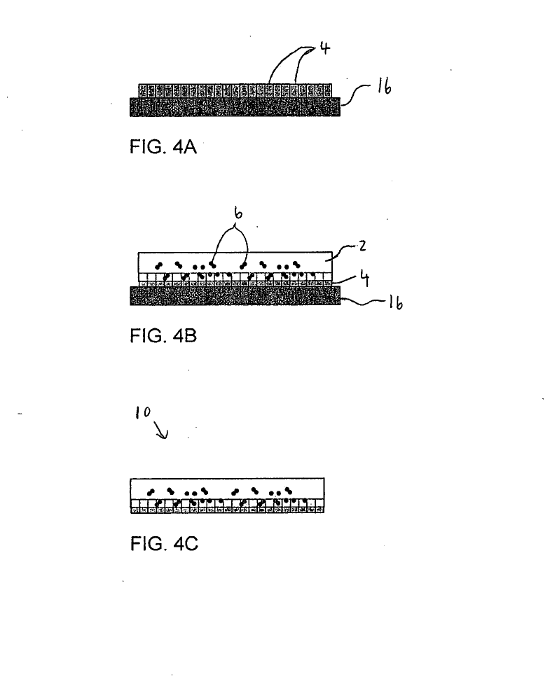

FIGS. 4A-4C illustrate a method of forming composite article 10 (FIG. 1), according to one embodiment of the invention. The method illustrated in FIG. 4 may be used to form an energy storage device (e.g., of FIGS. 2 and 3).

FIG. 4A illustrates the forming of elongated conductive structures 4 on a substrate 16. Any suitable substrate may be used for forming the elongated conductive structures. For example, a metal such as iron and/or aluminum may be electron-beam deposited on an insulating film, such as silicon dioxide. The silicon dioxide film may be formed on a silicon wafer. In some embodiments, the metal may be patterned so that elongated conductive structures are formed in a particular pattern. After the optional patterning of the substrate, the elongated conductive structures 4 are formed. For example, if the elongated conductive structures are carbon nanotubes, aligned elongated conductive structures may be formed by chemical vapor deposition.

FIG. 4B illustrates the formation of the composite article 10, with elongated conductive structures 4 embedded in polymer matrix 2. Polymer matrix 2 may be formed using a solution of polymer and liquid 6. Liquid 6 may be heated to dissolve the polymer in the liquid. The solution may be infiltrated into the polymer matrix 2 in any suitable way, e.g., by pouring the solution onto the elongated conductive structures 4. The polymer may be solidified into the polymer matrix by cooling the solution to precipitate the polymer out of the solution. As one example, the polymer may be cooled, using dry ice, to the sublimation point of carbon dioxide. Excess liquid 6 may be removed using any suitable means, such as drying in a vacuum and/or ethanol immersion.

FIG. 4C illustrates the composite article 10 with the substrate 16 removed. Substrate 16 may be removed in any suitable way. For example, composite article 10 may be peeled off the substrate 16.

If an energy storage device is to be formed, additional steps may be performed. For example, if capacitor 20 is to be formed, the method illustrated in FIG. 4 may be performed to produce two composite articles 10A, 10B, and the two composite articles may be brought into contact as illustrated in FIG. 2. If battery 30 is to be formed, the method illustrated in FIG. 4 may be followed with the application of an appropriate second electrode to composite article 10. Furthermore, an electrical conductor 12 may 10 be attached to an electrode as appropriate, for example, to make a suitable contact to the electrode.

The Applicants have further appreciated that it may be advantageous to produce composite article 10, capacitor 20 and/or battery 30 in a continuous process so that many such devices may be produced quickly and efficiently. For example, capacitor 20 may be formed by forming both electrodes simultaneously, then applying the polymer to the structure.

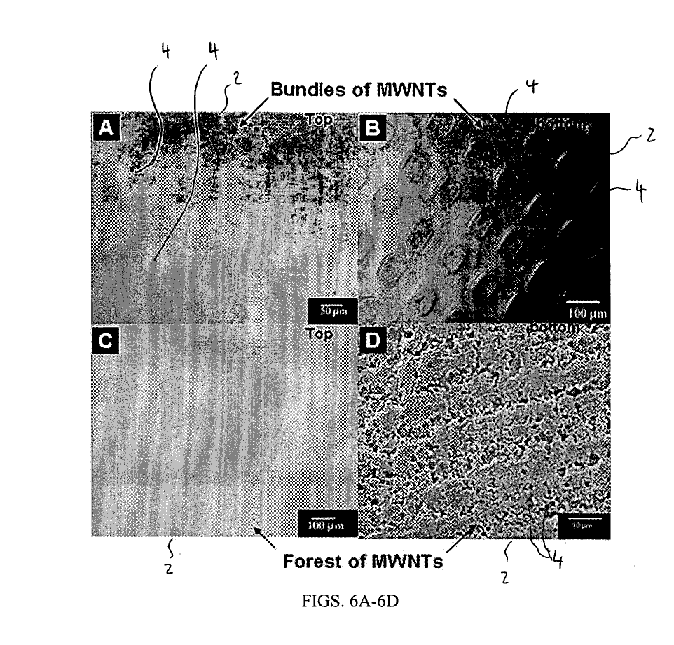

FIG. 6 shows images of composite article 10 according to some embodiments of the invention. FIG. 6A shows a top view of composite article 10 having an array of “bundles” of nanotubes, looking down through polymer matrix 2 at elongated conductive 20 structures 4. Multiple bundles of elongated conductive structures 4 can be seen embedded within and below the main surface 8 of polymer matrix 2. FIG. 6B shows a bottom view of composite article 10, looking up at the bundles of elongated conductive structures 4 and the polymer matrix 2. The elongated conductive structures are more easily seen in FIG. 6B than in FIG. 6A because portions of the elongated conductive structures are exposed at the bottom of composite article 10. FIG. 6C shows a top view of composite article 10 having a continuous “forest” of nanotubes. In this top view figure, only polymer matrix 2 is visible. FIG. 6D shows a bottom view of composite article 10 having the continuous forest of nanotubes.

Further images of elongated conductive structures 4 are shown in FIG. 9. FIG. 30 9A shows a side view of elongated conductive structures 4, in the form of carbon nanotubes. In this image, the elongated conductive structures are shown to be substantially aligned with one another, and perpendicular to the underlying substrate. FIG. 9B shows a top view of the elongated conductive structures 4.

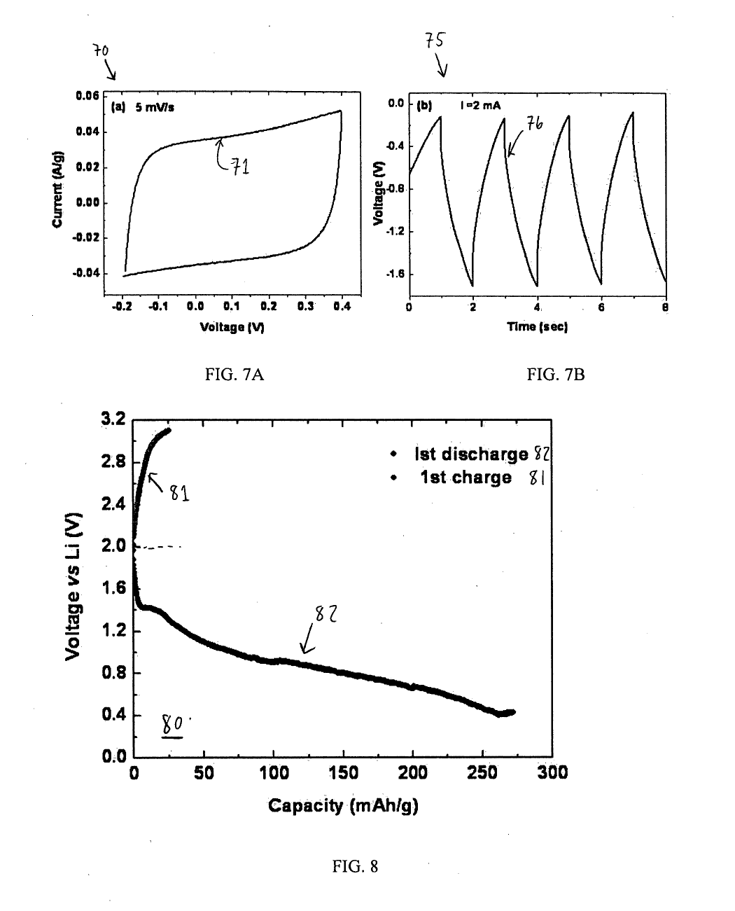

FIGS. 7 and 8 show plots that represent the electrical performance of capacitor 20 and battery 30, respectively, as experimentally measured. These experimental results demonstrate excellent capacitive behavior for capacitor 20, and good performance for battery 30.

FIG. 7A shows a cyclic voltammogram 70 of capacitor 20 at a scan rate of 20 mV/s. The nearly rectangular and symmetric shape of capacitance-voltage curve 71 reveals a low contact resistance, close to the ideal capacitor behavior. FIG. 7B shows a plot 75 of the galvanostatic charge-discharge behavior of capacitor 20 with an applied constant current of 2 mA. The symmetry of the charge-discharge curve 76 shows a nearly ideal capacitive behavior. The capacitance value, measured from the charge-discharge curve 76 at a constant of 2 mA, was measured to be 18 F/g.

FIG. 8 shows a plot 80 of the charge-discharge cycle behavior of battery 30, at a constant current of 50 mA/g. Plot 80 shows a first charge curve 81 and a first discharge curve 82. The large initial capacity is believed to be due to irreversible reactions occurring upon initial use.

### EXAMPLE 1

The following non-limiting example illustrates laboratory production and characterization of composite structures and energy storage devices based on such structures.

Carbon Nanotube Growth: Vertically aligned carbon nanotube (CNT) films on patterned and unpatterned substrates were prepared by a water-assisted chemical vapor deposition process. Typically, a 10 nm Al layer and 1-3 nm Fe layer were deposited by e-beam on the surface of 1 μm thick SiO₂ covered Si wafer. Ethylene was used as carbon source, and Ar/H₂ (15% H₂ content) as buffer gas. In a typical CVD growth run, 300 sccm Ar/H₂ flowed through an alumina tube during the furnace heating up to the CNT growth temperature (750-800° C.). After the furnace reached the set temperature, the Ar/H₂ flow was immediately increased to 1300 sccm, and another fraction of Ar/H₂ gas was bubbled through a water bottle (which was kept at room temperature) with a flow rate of 80 sccm, and ethylene gas was passed at a rate of 100 sccm into the Ar/H₂ gas mixture. The CNT growth lasted for 20 to 30 min. After that, the furnace was cooled down to room temperature under Ar/H₂ protection. The thickness of the resultant multi-wall nanotube (MWNT) forest was about 200·800 μm. The average diameter of MWNT was about 8 nm according to TEM observation.
Dissolution of Cellulose in Ionic Liquid: Cellulose was dissolved in a room temperature ionic liquid (RTIL) of [bmIm][Cl] (1.0 g) by preheating the RTIL to 70° C., and then adding 37.5 mg of cellulose. The contents were then mixed by vortexing and microwaved for 4-5 s, to afford a 3.75% (w/w) cellulose in [bmIm][Cl] composite solution.
Infiltration of CNT in cellulose matrix: The cellulose-RTIL solution was then poured on to the CNT-SiO₂ substrate at 70° C., and allowed to infiltrate the CNT arrays for 5 min. The whole substrate was then kept on dry ice for solidification. In one case, this composite was immersed in ethanol for 30 minutes to partially extract some amount of ionic liquid, while still leaving a significant amount of ionic liquid as electrolyte for the subsequently formed supercapacitors. In the second case, the composite was immersed in ethanol overnight to extract all the added ionic liquid. Ethanol dissolved only the ionic liquid—[bmIm][Cl], leaving the cellulose-CNT composite intact. The composite was dried in vacuo for 12 h to remove the residual ethanol. The RTIL could be easily recovered from the ethanol into which it dissolved by evaporating the ethanol, allowing both the ethanol and the RTIL to be recycled for use again. The dried cellulose film with infiltrated CNTs was peeled off the SiO₂ substrate to form an electrode that was further processed and characterized as described further below.

### Supercapacitor Characterization:

The electrochemical properties and capacitive measurements were studied for a supercapacitor formed from two such composite articles, and having no external spacer or other separator. The non-conducting polymer matrix itself acted as a separator and contained RTIL as the electrolyte. The composite articles were pressed in a Swagelok type stainless steel cell. Cyclic voltammetry and galvanostatic charge-discharge measurements were carried out using a Potentiostat/Galvanostat (EG&G Princeton Applied Research, Model 273A). Voltammetry testing was carried out at potentials between −0.6 V and 0.4 V. For calculating the specific capacitance galvanostatic charge-discharge behavior of the MWNTs, a constant current of 2 mA was applied in a time interval of 1 sec. The capacitance was evaluated from the slope of the charge-discharge curves, according to the following equation;

C=IΔt/ΔV

where I is the applied current.

### Battery Characterization:

The electrochemical performance testing of the composite article in a lithium battery was carried out using a Swagelok cell, where the lithium metal foil was used as the negative electrode. In this test, the composite article included cellulose as the polymer matrix, carbon nanotubes (embedded in the cellulose) as conducting filaments for a positive electrode, and a liquid electrolyte, which included 1 M LiPF₆, in ethylene carbonate, and dimethyl carbonate (1:1 by volume). No external separator was used for assembling the battery. The cells were assembled in an argon-filled glove box and then galvanostatically cycled between 3.1 V and 0.05 V using a Potentiostat/Galvanostat (EG&G Princeton Applied Research, Model 273A).

### Results and Discussion:

As described above, the dried cellulose-CNT composite film was peeled off the SiO₂ substrate. The film had very good flexibility and mechanical strength. A copy of a photograph of a CNT-cellulose composite film shown in FIG. 5 shows the flexibility of the film when being bent, while holding both the ends of the film.

The CNT bundles and CNT arrays were embedded in the cellulose matrix of the composite films. The resulting films were analyzed by scanning electron microscopy (SEM). SEM images are shown in FIGS. 6A-6D. The top and bottom views of the cellulose composite matrix with infiltrated CNT bundles are shown in FIGS. 6A and 6B, respectively; and the corresponding images of CNT forests are shown in FIGS. 6C and 6D, respectively.

It is clear from FIG. 6A that one end of the CNTs is completely embedded within the composite matrix, and the other end is exposed outside the composite. The high magnification images show the good alignment of CNTs in good packing density. The thickness of the composite film was measured by viewing the cross-section of the film using scanning electron microscopy, and was approximately 200 μm.

The cyclic voltammogram 70 of the supercapacitor is shown in FIG. 7A, at a scan rate of 20 mV/s. The rectangular and symmetric shape of the capacitance-voltage curve 71, close to ideal capacitor behavior, clearly reveals a low contact resistance. The galvanostatic charge-discharge behavior of the electrodes with an applied constant current of 2 mA is shown in FIG. 7B. The symmetry of the charge-discharge curve 76 shows good capacitive behavior. The capacitance value, measured from the charge-discharge curve at a constant current of 2 mA, was measured to be 18 F/g which is comparable to the values of electrochemical capacitors fabricated with carbon nanotubes.

The charge-discharge cycle behavior of the electrodes was measured during lithium insertion and extraction cycled between 3.1 V and 0.05 V at a constant current of 50 mA/g (FIG. 8). The larger initial capacity is due to the irreversible reactions occurring upon initial lithiation.

### EXAMPLE 2

The following example illustrates production and characterization of multi-wall nanotubes (MWNT) which may be suitable for use in composite structures.

50-100 micron MWNT were grown on quartz and silicon substrates through chemical vapor deposition. A gaseous mixture of ferrocene (0.3 g), as a catalyst source, and xylene (30 mL), as a carbon source, was heated to over 150° C. and passed over the substrate for 10 min, which was itself heated to 800° C. in a quartz tube furnace. The MWNT grew selectively on the oxide layer with controlled thickness and length. (The oxide layer of the substrate can be patterned by photolithography followed by a combination of wet and/or dry etching in order to create various patterns of MWNT.)

A scanning electron microscope (SEM) image of a typical MWNT forest grown on silicon is shown in FIGS. 9A and 9B. These tubes are vertically aligned with a typical diameter of 10-20 nm and length of 65 μm. The samples, with the MWNT side facing up, were then gently dipped in a beaker containing methyl methacrylate monomer (60 mL) and polymerized using a 2,2′-azobis(isobutyronitrile) initiator (0.17 g) and a 1-decanethiol chain transfer agent (30 μL) in a clean room. After the completion of polymerization in a water bath at 55° C. for 24 h, the samples were taken out by breaking the beaker. The MWNT are completely embedded and stabilized in the PMMA matrix. The PMMA-MWNT sheets were peeled off from the silicon substrates, forming a very smooth surface. The MWNT were exposed from the silicon-facing side of the PMMA matrix by etching the top 25 pm with a good solvent (acetone or toluene) for 50 min and subsequently washing with deionized water for 10 min. (The exposure length of the MWNT can be controlled by varying the solvent etching time.) As a control, blank PMMA films prepared using the same procedure, were etched with solvent and observed to maintain a very smooth surface. FIG. 9B shows MWNT brushes on PMMA films. Any patterns of MWNT on silicon can be exactly transferred on the top of the polymer surface. The brushes are mostly aligned vertically and in general form entangled bundles (of about 50 nm diameter) due to the solvent drying process. This creates surface roughness which, in turn, enhances adhesion of the MWNT.

### EXAMPLE 3

In this example, capacitors were prepared in accordance with the description above; however, a metal coating was deposited on an exposed (e.g., non-embedded) portion of the elongated conductive structures. With the addition of this metal coating as electrical conductor 12, advantageous capacitance and power density values were obtained by reducing the contact resistance.

### A. Supercapacitance Performance

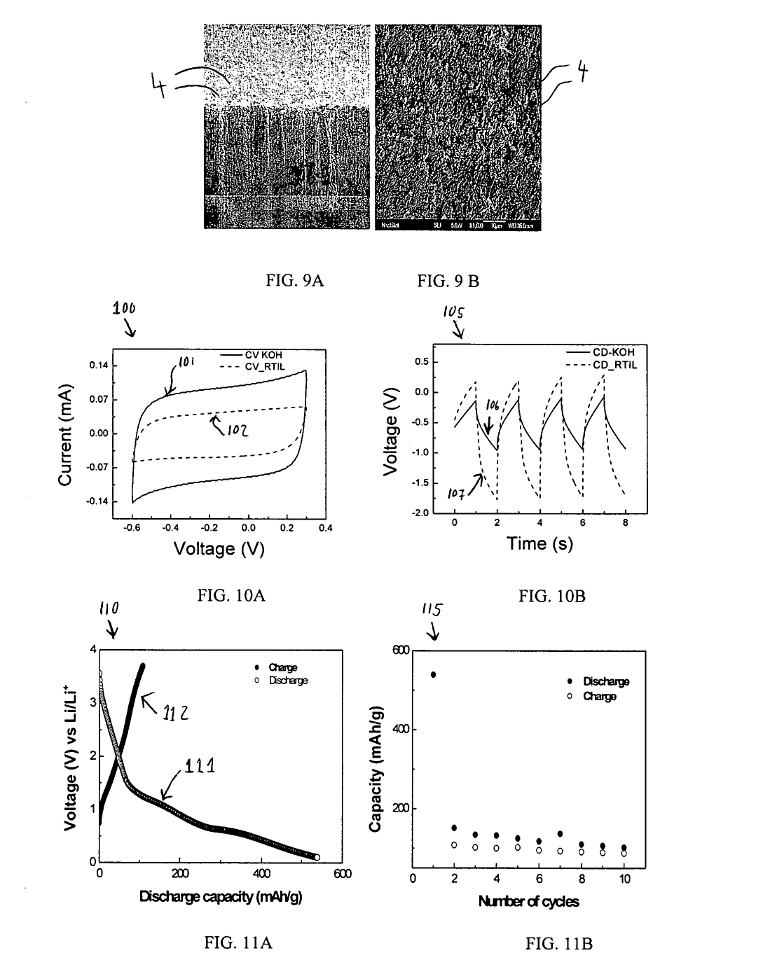

The charge-discharge curves were measured and a specific capacitance of 36 F/g and 22 F/g were calculated for the CNT-cellulose composite electrodes with KOH and RTIL electrolyte, respectively. A cyclic voltammogram 100 is shown in FIG. 10A, showing current-voltage curves 101 and 102 for supercapacitors with KOH or RTIL electrolyte, respectively. A plot 105 showing charge-discharge curves 106 and 107 of the supercapacitors are shown in FIG. 10B, each supercapacitor having either KOH or RTIL electrolyte, respectively.

### B. Li-Battery Performance

The capacity/voltage plot 110 shows curves 111, 112 shown in FIG. 11A show examples of battery performance during the first discharging (curve 111) and charging (curve 112) cycles. FIG. 11A shows capacity versus voltage curves, and FIG. 11B shows a plot 115 capacity versus cycle number for a lithium battery. An irreversible capacity of 430 mAh/g was obtained. Further charging and discharging cycles resulted in a reversible capacity of ˜110 mAh/g, which was stable over 10 cycles (FIG. 11B).

### EXAMPLE 4

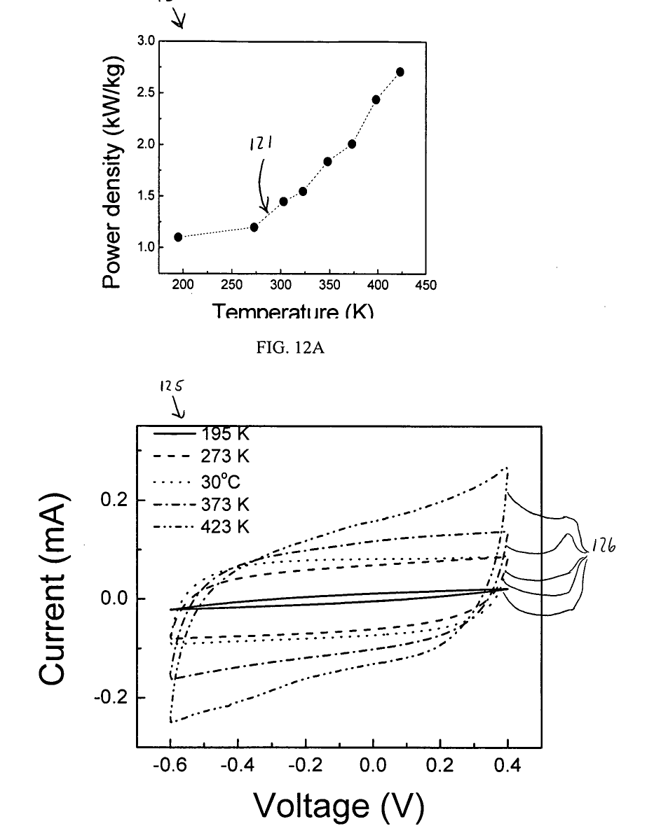

In this example, capacitors were prepared in accordance with the description above, and performance of the capacitors was tested at different temperatures. A plot 120 of the electrochemical properties of one example of a supercapacitor (CNT-cellulose/RTIL composite), as a function of temperature, is shown in FIG. 12A (Power density versus temperature), and the performance is shown as curve 121. FIG. 12B shows a cyclic voltammogram 125, showing current-voltage curves 126 as a function of supercapacitor temperature. The supercapacitor device was heated to different temperatures and the cyclic voltammetry measurements were carried out. The current-voltage area gives the measure of the power density of the supercapacitor, and is found to increase with increased temperature. The measurement was also made at 77 degrees K, but there was no capacitive behavior observed at this temperature. However, the device regained its capacitive behavior once the temperature exceeded 195 degrees K. This clearly shows the supercapacitor functions through a wide range of operating temperatures (195 K to 423 K). Hence, the supercapacitor can be useful for portable devices used under extreme weather conditions, such as those encountered in military applications.

### EXAMPLE 5

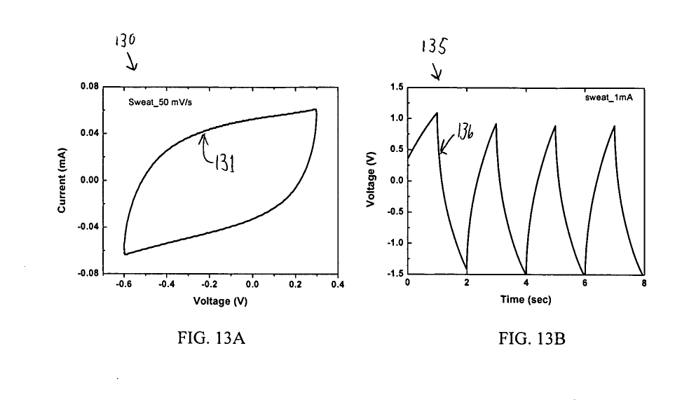

In this example, capacitors were prepared in accordance with the description above, but using human perspiration (e.g., sweat) as an electrolyte. FIG. 13A shows a cyclic voltammogram 130, showing current-voltage curve 131, and FIG. 14B shows a plot 135, showing a charge-discharge curve 136 of a supercapacitor in which human perspiration was used as the electrolyte. Since the mechanism of charge storage in a supercapacitor is due to the movement of ions to and from the electrode surfaces, we undertook an experiment using human perspiration as the electrolyte in the supercapacitor. In this experiment, RTIL was completely extracted using ethanol and human perspiration was used as an alternative electrolyte. Good capacitive behavior was observed (FIG. 13A), with a specific capacitance of 12 F/g (FIG. 13B). This supercapacitor also showed an operating voltage of around 2.4 V, which is promising for high-energy applications. This supercapacitor could be used for the fabrication of self-sustainable supercapacitor devices, which could overcome the packaging problem arising from the aqueous electrolytes.

Having thus described several aspects of at least one embodiment of this invention, it is to be appreciated various alterations, modifications, and improvements will readily occur to those skilled in the art. Such alterations, modifications, and improvements are intended to be part of this disclosure, and are intended to be within the spirit and scope of the invention. Accordingly, the foregoing description and drawings are by way of example only.

What is claimed is:

1. An energy storage device, comprising:
a non-conductive polymer matrix;
a first electrode comprising first elongated conductive structures embedded in the polymer matrix;
a second electrode; and
a liquid comprising ionic species contained within the polymer matrix.

2. The energy storage device of claim 1, wherein the energy storage device comprises a capacitor.

3. The energy storage device of claim 2, wherein:
the capacitor is a supercapacitor; and
the second electrode comprises second elongated conductive structures embedded in a polymer matrix.

4. The energy storage device of claim 3, wherein the first elongated conductive structures are embedded in a first polymer matrix and second elongated conductive structures are embedded in a second polymer matrix.

5. The energy storage device of claim 4, wherein the first and second polymer matrices contact each other.

6. The energy storage device of claim 4, wherein the first and second elongated conductive structures are embedded in the same polymer matrix.

7. The energy storage device of claim 2, wherein the device is free of a separate non-conductive spacer.

8. The energy storage device of claim 1, wherein the energy storage device comprises a battery.

9. The energy storage device of claim 8, wherein the second electrode comprises lithium.

10. The energy storage device of claim 8, wherein the liquid comprises a lithium salt.

11. The energy storage device of claim 8, wherein the liquid comprises at least one of LiPF₆, LiClO₄, LiAsF₆ and Li salts.

12. The energy storage device of claim 1, further comprising a conductive material that electrically contacts the first electrode.

13. The energy storage device of claim 12, wherein the conductive material is in a form of a conductive film, and at least a substantial portion of the elongated conductive structures are aligned perpendicular to the conductive film.

14. The energy storage device of claim 2, wherein the capacitor is operable over substantially an entire temperature range from approximately 195 to 423 degrees Kelvin.

15. The energy storage device of claim 1, wherein the energy storage device is designed to provide energy to at least one of a sensor, temperature sensor, switch, drug delivery device, pacemaker, implantable device, mobile device, MEMS device, NEMS device, RFID device, system on a chip and artificial organ.

16. The energy storage device of claim 1, wherein the energy storage device is designed to be attached to the human body.

17. The energy storage device of claim 1, wherein the energy storage device is shaped to be implanted within a portion of a human body.

18. The energy storage device of claim 1, wherein the polymer matrix comprises cellulose.

19. The energy storage device of claim 1, wherein the polymer matrix is porous.

20. The energy storage device of claim 1, wherein a substantial portion of the elongated conductive structures are aligned with one another.

21. The energy storage device of claim 1, wherein the filaments are arranged in patterned bundles of filaments.

22. The energy storage device of claim 1, wherein the elongated conductive structures comprise carbon filaments.

23. The energy storage device of claim 22, wherein the carbon filaments comprise carbon nanotubes.

24. The energy storage device of claim 1, wherein the elongated conductive structures are embedded in the polymer matrix such that only respective end portions of at least some of the elongated conductive structures are exposed and remaining portions of the at least some of the elongated conductive structures are surrounded by the polymer matrix.

25. The energy storage device of claim 1, wherein the liquid is an electrolyte.

26. The energy storage device of claim 1, wherein the liquid contacts a substantial portion of a surface area of the elongated conductive structures.

27. The energy storage device of claim 1, wherein the liquid is a room temperature ionic liquid.

28. The energy storage device of claim 1, wherein the liquid comprises an aqueous solution.

29. The energy storage device of claim 28, wherein the aqueous solution is selected from the group consisting of sulfuric acid, potassium hydroxide and sodium hydroxide.

30. The energy storage device of claim 1, wherein the solution is a non-aqueous solution selected from the group consisting of propylene carbonate, dimethoxy ethanol, diethyl carbonate, and acetonitrile.

31. The energy storage device of claim 1, wherein the liquid comprises at least one of LiClO₄, NaClO₄, LiAsF₆, BF₄⁻ and quarternary phosphonium salts.

32. The energy storage device of claim 1, wherein the energy storage device has substantial mechanical flexibility.

33. The energy storage device of claim 1, wherein an amount of the liquid present in the polymer, by weight, is between about 5% and 30% of a total weight of the energy storage device.

34. The energy storage device of claim 1, wherein the first electrode and the polymer matrix are formed as a film.

35. The energy storage device of claim 1, wherein the liquid is dispersed within the polymer matrix.

36. The energy storage device of claim 1, wherein the liquid comprises a bodily fluid.

37. The energy storage device of claim 3, wherein the first electrode, the second electrode and the polymer matrix are formed as a single film, such that the first elongated conductive structures and the second elongated conductive structures are embedded in a same polymer matrix and are separated from one other by a portion of the polymer matrix.

38. A composite article, comprising:
a non-conductive polymer matrix;
a plurality of elongated conductive structures embedded in the polymer matrix; and
a liquid comprising ionic species contained within the polymer matrix.

39. The article of claim 38, wherein the polymer matrix comprises cellulose.

40. The article of claim 38, wherein the polymer matrix is porous.

41. The article of claim 38, wherein a substantial portion of the elongated conductive structures are aligned with one another.

42. The article of claim 38, wherein substantially all of the elongated conductive structures are aligned with one another.

43. The article of claim 38, wherein the elongated conductive structures comprise carbon nanotubes.

44. The article of claim 38, wherein the elongated conductive structures are embedded in the polymer matrix such that only respective end portions of at least some of the elongated conductive structures are exposed and remaining portions of the at least some of the elongated conductive structures are surrounded by the polymer matrix.

45. The article of claim 38, wherein the liquid is an electrolyte.

46. The article of claim 38, wherein the liquid contacts a substantial portion of a surface area of the elongated conductive structures.

47. The article of claim 38, wherein the liquid is a room temperature ionic liquid.

48. The article of claim 38, wherein the article comprises at least a portion of an energy storage device.

49. The article of claim 38, wherein the article is shaped to be implanted within a portion of the human body.

50. The article of claim 38, wherein the article is part of a sensor designed to be implanted within or attached to the human body.

51. A method of forming a composite article, the method comprising:
forming a set of elongated conductive structures;
infiltrating the set of elongated conductive structures with a solution of polymer and liquid; and
forming a composite article comprising the set of elongated conductive structures embedded in a non-conductive polymer matrix.

52. The method of claim 51, wherein the set of elongated conductive structures is formed on a substrate using chemical vapor deposition.

53. The method of claim 51, further comprising:
forming a metal layer on a substrate;
patterning the metal, prior to forming the set of elongated conductive structures; and
forming the elongated conductive structures in a pattern that corresponds to the patterning of the metal.

54. The method of claim 51, further comprising:
prior to infiltrating the set of elongated conductive structures with the solution, forming the solution by heating the liquid to dissolve the polymer in the liquid.

55. The method of claim 51, wherein infiltrating the set of elongated conductive structures comprises pouring the solution into the set of elongated conductive structures.

56. The method of claim 51, wherein forming the composite article comprises solidifying the polymer into the polymer matrix.

57. The method of claim 56, wherein solidifying the polymer into the polymer matrix comprises cooling the solution to precipitate at least a portion of the polymer matrix from the solution.

58. The method of claim 57, wherein the polymer is cooled to a temperature approximately equal to a sublimation point of carbon dioxide to solidify the polymer.

59. The method of claim 51, further comprising: removing a portion of the liquid.

60. The method of claim 59, wherein removing the portion of the liquid comprises drying the composite article in a vacuum.

61. The method of claim 59, wherein removing the portion of the liquid comprises immersing the composite article in ethanol.

62. The method of claim 51, further comprising:
forming the composite article in a desired shape.

63. The method of claim 62, wherein the forming of the composite article into the desired shape comprises pouring the solution into a mold that has the desired shape prior to forming the composite article.

64. The method of claim 62, wherein the desired shape is a shape designed to fit within a specified region of an object.

65. The method of claim 51 wherein the forming of the set of elongated conductive structures comprises:
forming first elongated conductive structures; and
forming a conductive layer on the first elongated conductive structures.
